(19) United States
(12) Patent Application Publication
(10) Pub. No.: US 2026/0047323 A1
(43) Pub. Date: Feb. 12, 2026

(54) DISPLAY APPARATUS, METHOD OF MANUFACTURING THE SAME, AND ELECTRONIC DEVICE

(71) Applicant: Samsung Display Co., LTD., Yongin-si (KR)

(72) Inventors: Wonbeom Lee, Yongin-si (KR); Yonghoon Kwon, Yongin-si (KR); Dongsung Lee, Yongin-si (KR)

(21) Appl. No.: 19/250,843

(22) Filed: Jun. 26, 2025

(30) Foreign Application Priority Data
Aug. 9, 2024 (KR) 10-2024-0107083

(51) Int. Cl. H10K 59/80; H10K 102/00

(52) U.S. Cl. CPC H10K 59/8792; H10K 59/871; H10K 2102/311; H10K 2102/351

(57) ABSTRACT

A display apparatus in which damage during the manufacturing process is minimized includes a display panel divided into a display area, where an image is displayed, and a peripheral area surrounding the display area, wherein the peripheral area includes a bending area bendable around a bending axis, an upper protective layer disposed on the display panel in the display area, a cover layer disposed on the upper protective layer and overlapping with the display area in a plan view, a bending protective layer disposed on the display panel in the bending area and a light-absorbing layer disposed on the display panel between the upper protective layer and the bending protective layer, overlapping with one edge of the cover layer in a plan view, and including a plurality of light-absorbing agents.

This application claims priority to Korean Patent Application No. 10-2024-0107083, filed on Aug. 9, 2024, and all the benefits accruing therefrom under 35 U.S. C. § 119, the content of which in its entirety is herein incorporated by reference.

### BACKGROUND

### 1. Field

The invention relates to a display apparatus, a method of manufacturing the same, and an electronic device, and more particularly, to a display apparatus in which damage during the manufacturing process is minimized, a method of manufacturing the display apparatus, and an electronic device.

### 2. Description of the Related Art

A display apparatus is a device that receives information about an image and displays the image. The display apparatus may be used as a display part of small products such as mobile phones, or as a display part of large products such as televisions.

The display apparatus includes a plurality of pixels that receive electrical signals and emit light so as to display images externally. Each pixel includes a light-emitting element, and for example, in the case of an organic light-emitting display apparatus, the organic light-emitting display apparatus includes an organic light-emitting diode as the light-emitting element. Generally, an organic light-emitting display apparatus forms a thin-film transistor and an organic light-emitting diode on a substrate and operates by the organic light-emitting diode emitting light by itself.

An electronic device may provide a visual interface to a user through the display apparatus.

### SUMMARY

One or more embodiments include a display apparatus in which damage during the manufacturing process is minimized, a method of manufacturing the same, and an electronic device.

Additional aspects will be set forth in part in the description which follows and, in part, will be apparent from the description, or may be learned by practice of the presented embodiments.

According to one or more embodiments, a display apparatus includes a display panel divided into a display area where an image is displayed and a peripheral area surrounding the display area, wherein the peripheral area includes a bendable bending area, an upper protective layer disposed on the display panel in the display area, a cover layer disposed on the upper protective layer and overlapping with the display area in a plan view, a bending protective layer disposed on the display panel in the bending area, and a light-absorbing layer disposed on the display panel between the upper protective layer and the bending protective layer, overlapping with one edge of the cover layer in a plan view, and including a plurality of light-absorbing agents.

According to one or more embodiments, the light-absorbing layer may include a resin layer including the plurality of light-absorbing agents.

According to one or more embodiments, each of the plurality of light-absorbing agents may include carbon black particles wherein each of the carbon black particles has a diameter of about 150 nanometers or less.

According to one or more embodiments, wherein among edges of the cover layer, an edge closest to the bending area may overlap with the light-absorbing layer in a plan view.

According to one or more embodiments, the cover layer may include: a first layer disposed on the upper protective layer and a second layer disposed on the first layer and including a resin

According to one or more embodiments, the one edge may be formed by laser cutting.

According to one or more embodiments, ultraviolet (UV) wavelength transmittance of the light-absorbing layer may be less than about 10%.

According to one or more embodiments, a thickness of the light-absorbing layer may be less than a thickness of the bending protective layer.

According to one or more embodiments, the thickness of the bending protective layer may be less than the thickness of an upper protective layer.

According to one or more embodiments, a method of manufacturing a display apparatus includes a display panel divided into a display area where an image is displayed and a peripheral area surrounding the display area according to an embodiment of the present disclosure, wherein the peripheral area includes a bendable bending area, may include, disposing an upper protective layer on the display area of the display panel, disposing a bending protective layer on the bending area of the display panel, forming a light-absorbing layer including a plurality of light-absorbing agents between the upper protective layer and the bending protective layer in a plan view, forming a cover layer on the upper protective layer and cutting the cover layer by using a laser process, wherein an average thickness of the light-absorbing layer may decrease due to the laser process. The display panel may be divided into a display area where images are displayed and a peripheral area surrounding the display area, and the peripheral area may include a bendable bending area centered on a bending axis.

According to one or more embodiments, the average thickness of the light-absorbing layer before the cutting may be larger than the average thickness of the light-absorbing layer before the cutting.

According to one or more embodiments, one edge of the cover layer formed by the laser process may overlap with the light-absorbing agent in a plan view.

According to one or more embodiments, the light-absorbing layer may include a resin layer including the plurality of light-absorbing agents.

According to one or more embodiments, each of the plurality of light-absorbing agents may include carbon black particles, wherein each of the carbon black particles have a diameter of about 150 nanometers or less.

According to one or more embodiments, the ultraviolet (UV) wavelength transmittance of the light-absorbing layer may be less than about 10%.

According to one or more embodiments, a thickness of the light-absorbing layer may be less than a thickness of the bending protective layer.

According to one or more embodiments, the thickness of the bending protective layer may be less than a thickness of the upper protective layer.

According to one or more embodiments, an electronic device includes a memory storing instructions, a processor configured to generate control commands by computing the instructions, and a display apparatus configured to display an image based on the control commands, wherein the display apparatus includes a display panel divided into a display area where an image is displayed and a peripheral area surrounding the display area, wherein the peripheral area includes a bendable bending area, an upper protective layer disposed on the display panel, a cover layer disposed on the upper protective layer and overlapping with the display area in a plan view, a bending protective layer disposed on the display panel in the bending area, and a light-absorbing layer disposed on the display panel between the upper protective layer and the bending protective layer, overlapping with one edge of the cover layer in a plan view, and including a plurality of light-absorbing agents.

According to one or more embodiments, the light-absorbing layer may include a resin layer including the plurality of light-absorbing agents.

According to one or more embodiments, a thickness of the light-absorbing layer may be less than a thickness of the bending protective layer, and the thickness of the bending protective layer may be less than a thickness of the upper protective layer.

### BRIEF DESCRIPTION OF THE DRAWINGS

The above and other aspects, features, and advantages of embodiments of the invention will be more apparent from the following description taken in conjunction with the accompanying drawings, in which:

FIG. 1 is a plan view illustrating a display panel of a display apparatus, according to an embodiment;

FIG. 2 is a side view illustrating the display panel of FIG. 1, according to an embodiment;

FIG. 3 is a cross-sectional view illustrating a cross-section obtained along a cutting line A-A′ of FIG. 1, according to an embodiment;

FIG. 4 is a cross-sectional view illustrating a portion of the display apparatus of FIG. 1 in a bent state, according to an embodiment;

FIG. 5 is a cross-sectional view illustrating a region A of FIG. 4, according to an embodiment;

FIG. 6 is a cross-sectional view illustrating a portion of the display apparatus of FIG. 1 in a bent state, according to an embodiment;

FIG. 7 is a cross-sectional view illustrating a portion of the display apparatus of FIG. 1 in a bent state, according to an embodiment;

FIG. 8 is a cross-sectional view illustrating a portion of the display apparatus of FIG. 1 in a bent state, according to an embodiment;

FIG. 9 is another example of a cross-sectional view illustrating a portion of the display apparatus, according to another embodiment; and

FIG. 10 is a conceptual diagram illustrating an electronic device including the display apparatus of FIG. 1, according to an embodiment.

### DETAILED DESCRIPTION

Reference will now be made in detail to embodiments, examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The invention may be subject to various modifications and may have various embodiments, and specific embodiments will be illustrated in the drawings and described in detail in the detailed description. The effects and features of the invention, and methods for achieving them will be more apparent from the embodiments described below with reference to the drawings. However, the invention is not limited to the embodiments disclosed below but may be implemented in various forms.

Hereinafter, embodiments will be described in detail with reference to the accompanying drawings. When explaining the embodiments with reference to the drawings, the same or corresponding components will be given the same reference numerals, and redundant explanations thereof will be omitted.

In the following embodiments, the terms “first,” “second,” etc. are used for distinguishing one component from another component, not in a limiting sense. Also, in the following embodiments, singular expressions include plural expressions unless the context clearly indicates otherwise.

In the following embodiments, when a layer, film, region, plate, or various components are said to be “on” another component, this description includes not only cases where they are “directly on” the other component but also cases where other components are interposed between the layer, film, region, plate, or various components and the other component.

Also, for the convenience of explanation, the size or thickness of components in the drawings may be exaggerated or reduced. For example, the size and thickness of each component shown in the drawings are arbitrarily shown for convenience of explanation, and thus the present disclosure is not necessarily limited to what is shown.

In the following embodiments, terms such as “include” or “have” mean that features or components described in the specification exist, and do not preclude the possibility of one or more other features or components being added.

In the following embodiments, when a part of a film, region, or component is said to be “on” or “above” another part, this description includes not only cases where the part of the film, region, or component is directly on the other part but also cases where other films, regions, or components are interposed between the part of the film, region, or component and the other part.

When a particular process order is described, unless otherwise implementable, a specific process may be performed in a different order from the described order. For example, two processes described consecutively may be performed substantially simultaneously or in the reverse order of the described order.

In the following embodiments, when films, regions, or components are said to be connected, it includes cases where the films, regions, or components are directly connected, and/or cases where other films, regions, or components are interposed between them and indirectly connected. For example, in this specification, when films, regions, or components are said to be electrically connected, this description indicates cases where the films, regions, or components are directly electrically connected, and/or cases where other films, regions, or components are interposed between them and indirectly electrically connected.

In the following embodiments, the x-axis, y-axis, and z-axis are not limited to three axes in an orthogonal coordinate system but may be interpreted in a broader sense including this. For example, the x-axis, y-axis, and z-axis may be orthogonal to each other, or may refer to different directions that are not orthogonal to each other.

Hereinafter, based on the above-mentioned contents, one or more embodiments, including a display apparatus, a method of manufacturing the same, and an electronic device, will be described in detail as follows.

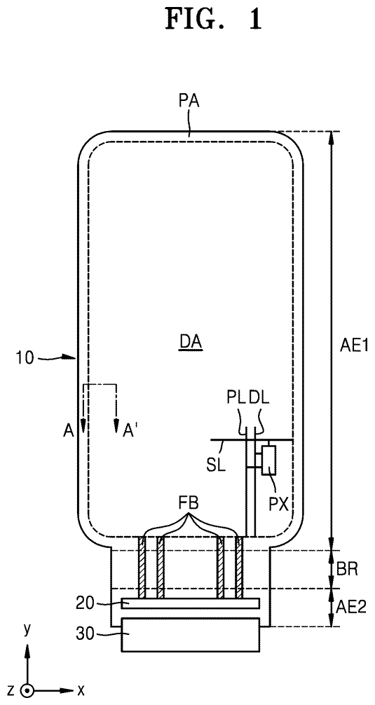

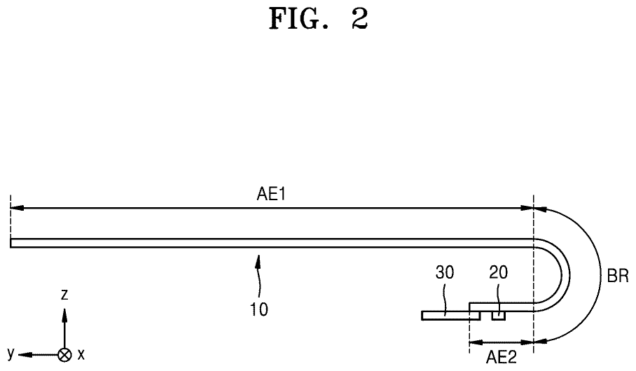

FIG. 1 is a plan view illustrating a display panel of a display apparatus, according to an embodiment, and FIG. 2 is a side view illustrating the display panel of FIG. 1, according to an embodiment.

As shown in FIGS. 1 and 2, the display apparatus, according to an embodiment, includes a display panel 10. This display apparatus may include anything that includes the display panel 10.

In an embodiment, the display apparatus is a device that displays moving or still images and may be used as a display screen for various products such as portable electronic device including mobile phone, smartphone, tablet personal computer (PC), mobile communication terminal, electronic notebook, electronic book, portable multimedia player (PMP), navigation devices, Ultra Mobile PC (UMPC), as well as televisions, laptops, monitors, advertising boards, and Internet of Things (IoT) devices. Also, according to an embodiment, the display apparatus may be used in wearable devices such as smart watches, watch phones, glasses-type displays, and head-mounted displays (HMD). Additionally, according to an embodiment, the display apparatus may be used as an instrument panel for automobiles, a Center Information Display (CID) disposed in the center fascia or dashboard of automobiles, a room mirror display replacing side mirrors of automobiles, or a display disposed on the back of front seats for rear-seat entertainment in automobiles.

In an embodiment, the display panel 10 includes a display area DA and a peripheral area PA disposed outside of the display area DA. The display area DA is a portion where images are displayed, and a plurality of pixels PX may be disposed in the display area DA. When viewed in a direction that is directed substantially perpendicular to the display panel 10, the display area DA may have various shapes such as circular, oval, polygonal, or specific geometric shapes. FIG. 1 shows the display area DA having a roughly rectangular shape with rounded corners.

In an embodiment, the peripheral area PA may be disposed outside the display area DA. The width in the x-axis direction of a portion of the peripheral area PA may be narrower than the width in the x-axis direction of the display area DA. Through this structure, as described below, the portion of the peripheral area PA can be easily bent.

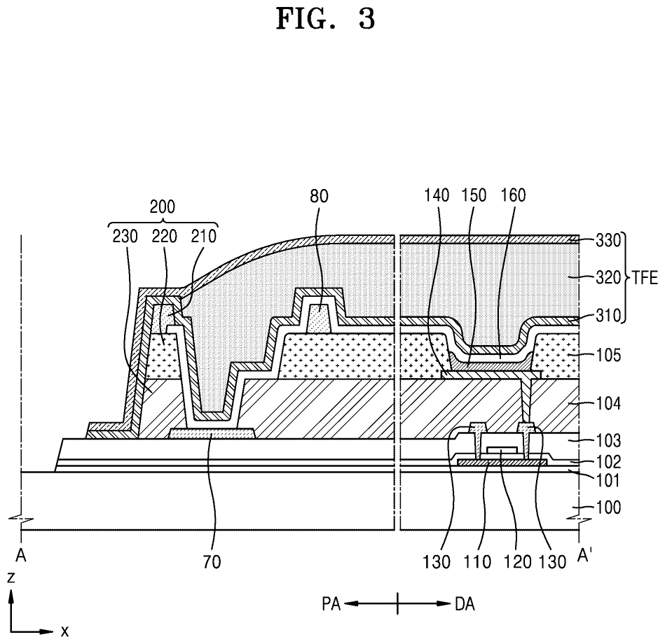

In an embodiment, since the display panel 10 includes the substrate 100 (See FIG. 3) to be described below, the substrate 100 can also be said to have the display area DA and the peripheral area PA as described above. Hereinafter, for convenience, the description will explain that the substrate 100 or the display panel 10 has the display area DA and the peripheral area PA.

In an embodiment, the display panel 10 may also be said to have a main area AE1, a bending area BR located outside the main area AE1, and a sub-area AE2 located on the opposite side of the main area AE1 centered on the bending area BR. In the bending area BR, as shown in FIG. 2, the display panel 10 may be bent so that when viewed from the z-axis direction, a portion of the sub-area AE2 overlaps with the main area AE1. The invention is not limited to a bent display apparatus and may also be applied to a non-bent display apparatus. The sub-area AE2 may be a non-display area or may include a non-display area, as described below. By making the display panel 10 bend at the bending area BR, when viewing the display apparatus from the front (−z direction), the non-display area may not be visible or, even if visible, the visible area of the non-display area may be minimized.

In an embodiment, a driving chip 20 may be disposed in the sub-area AE2 of the display panel 10, where the driving chip 20 may include an integrated circuit that drives the display panel 10. This integrated circuit may be a data driving integrated circuit that generates data signals, but the invention is not limited to this specific type of integrated circuit.

In an embodiment, the driving chip 20 may be mounted in the sub-area AE2 of the display panel 10, where the driving chip 20 is mounted on the same surface as the display surface of the display area DA, but as mentioned earlier, as the display panel 10 is bent at the bending area BR, the driving chip 20 may be positioned on the back surface of the main area AE1.

In an embodiment, a printed circuit board 30 or the like may be attached to the end of the sub-area AE2 of the display panel 10. This printed circuit board 30 or the like may be electrically connected to the driving chip 20 or the like through a pad not shown on the substrate.

In an embodiment and as shown in FIG. 1, fan-out wiring FB may be disposed in the peripheral area. The fan-out wiring FB may be disposed along the bending area BR and may be bent together as the bending area BR is bent. For example, the fan-out wiring FB may electrically connect the driving chip 20 and components of the display area DA for example, pixels PX, or may be touch wiring not shown.

Hereinafter, an organic light-emitting display apparatus will be described as an example of the display apparatus according to an embodiment, but the display apparatus of the invention is not limited to this. In another embodiment, the display apparatus of the invention may be an inorganic light-emitting display apparatus or a quantum dot light-emitting display apparatus. For example, the light-emitting layer of a display element included in the display apparatus may include organic materials or inorganic materials. Also, the display apparatus may include a light-emitting layer and a quantum dot layer located in the path of light emitted from the light-emitting layer.

In an embodiment, the display area DA is the portion where images are displayed, and a plurality of pixels PX may be disposed. Each pixel PX may include the display element such as an organic light-emitting diode. Each pixel PX may emit light of one of red, green, or blue colors. The pixels PX may be connected to a pixel circuit including thin-film transistors Thin Film Transistor (TFT, storage capacitors, etc.). The pixel circuit may be connected to scan lines SL that transmit scan signals, data lines DL that cross the scan lines SL and transmit data signals, and driving voltage lines PL that supply driving voltages. The scan lines SL may extend in the x-axis direction, and the data lines DL and driving voltage lines PL may extend in the y-axis direction.

In an embodiment, the pixel PX may emit light with a luminance corresponding to the electrical signal from the electrically connected pixel circuit. The display area DA may display a certain image through the light emitted from the pixels PX.

FIG. 3 is a cross-sectional view illustrating a cross-section obtained along the A-A′ cutting line of FIG. 1, according to an embodiment.

In an embodiment, the substrate 100 may include areas corresponding to the display area DA and the peripheral area PA disposed outside the display area, as mentioned earlier. The substrate 100 may include various materials with flexible or bendable characteristics. For example, the substrate 100 may include glass, metal, or polymer resin. Also, the substrate 100 may include polyethersulfone, polyacrylate, polyetherimide, polyethylene naphthalate, polyethylene terephthalate, polyphenylene sulfide, polyarylate, polyimide, polycarbonate, or cellulose acetate propionate. In an embodiment, the substrate 100 may have a multilayer structure including two layers each containing such polymer resins and a barrier layer containing inorganic material such as silicon oxide, silicon nitride, silicon oxynitride, etc. interposed between those layers, and various modifications are possible.

In an embodiment, a buffer layer 101 may be located on the substrate 100 and may act as a barrier layer and/or blocking layer to prevent the diffusion of impurity ions, prevent the penetration of moisture or external air, and planarize the surface of the substrate 100. The buffer layer 101 may include silicon oxide, silicon nitride, or silicon oxynitride. Also, the buffer layer 101 may control the rate of heat provision during the crystallization process for forming the semiconductor layer 110, allowing the semiconductor layer 110 to crystallize uniformly.

In an embodiment, a semiconductor layer 110 may be located on the buffer layer 101 and may include polysilicon and may include a channel region not doped with impurities, and source and drain regions formed by being doped with impurities on both sides of the channel region. Here, the impurities may vary depending on the type of thin-film transistor and may be N-type impurities or P-type impurities.

In an embodiment, a gate insulating film 102 may be located on the semiconductor layer 110, where the gate insulating film 102 may be a component to ensure insulation between the semiconductor layer 110 and the gate layer 120. The gate insulating film 102 may include inorganic materials such as silicon oxide, silicon nitride, and/or silicon oxynitride, and may be interposed between the semiconductor layer 110 and the gate layer 120. Also, the gate insulating film 102 may have a shape formed corresponding to the entire surface of the substrate 100, with contact holes formed in certain portions. Such insulating films containing inorganic materials may be formed through CVD chemical vapor deposition or ALD atomic layer deposition. The method of formation of insulating films through CVD or ALD applies to the subsequent embodiments and their variations as well.

In an embodiment, the gate layer 120 may be located on the gate insulating film 102 and may be disposed in a position vertically overlapping with the semiconductor layer 110, and may include at least one metal among molybdenum Mo, aluminum Al, platinum Pt, palladium Pd, silver Ag, magnesium Mg, gold Au, nickel Ni, neodymium Nd, iridium Ir, chromium Cr, nickel Li, calcium Ca, titanium Ti, tungsten W, copper Cu.

In an embodiment, an interlayer insulating film 103 may be located on the gate layer 120 and may cover the gate layer 120. The interlayer insulating film 103 may include inorganic material. For example, the interlayer insulating film 103 may be a metal oxide or metal nitride, and specifically, the inorganic material may include silicon oxide SiO₂, silicon nitride SiNx, silicon oxynitride SiON, aluminum oxide Al₂O₃, titanium oxide TiO₂, tantalum oxide Ta₂O₅, hafnium oxide HfO₂, or zinc oxide ZrO₂. In some embodiments, the interlayer insulating film 103 may have a double structure of SiOx/SiNy or SiNx/SiOy.

In an embodiment, a first conductive layer 130 may be located on top of the interlayer insulating film 103, where the first conductive layer 130 may serve as an electrode connected to the source/drain regions of the semiconductor layer through a via hole included in the interlayer insulating film 103. The first conductive layer 130 may include one or more metals from among aluminum Al, platinum Pt, palladium Pd, silver Ag, magnesium Mg, gold Au, nickel Ni, neodymium Nd, iridium Ir, chromium Cr, nickel Li, calcium Ca, molybdenum Mo, titanium Ti, tungsten W, copper Cu. For example, the first conductive layer 130 may include a Ti layer, an Al layer, and/or a Cu layer.

In an embodiment, a first organic insulating layer 104 may be located on the first conductive layer 130, where the first organic insulating layer 104 may cover the top of the first conductive layer 130 and have a generally flat upper surface, serving as a planarization layer. The first organic insulating layer 104 may include organic materials such as acryl, Benzocyclobutene (BCB), or hexamethyldisiloxane (HMDSO). The first organic insulating layer 104 may be composed of a single layer or multiple layers, and various modifications are possible.

In an embodiment, although not shown in FIG. 3, additional conductive layers and additional insulating layers may be interposed between the conductive layer and the pixel electrode. In this case, the additional conductive layer may include the same material as the aforementioned conductive layer and may have the same layer structure. In an embodiment, the additional insulating layer may include the same material as the aforementioned organic insulating layer and may have the same layer structure.

In an embodiment, a pixel electrode 140 may be located on the organic insulating layer 104, where the pixel electrode 140 may be connected to the first conductive layer 130 through a contact hole formed in the organic insulating layer 104. A display element may be located on the pixel electrode 140. An organic light-emitting diode may be used as the display element. For example, the organic light-emitting diode may be interposed on the pixel electrode 140. The pixel electrode 140 may include a transparent conductive layer including a transparent conductive oxide such as ITO, In₂O₃ or IZO, and a reflective layer including a metal such as Al or Ag. For example, the pixel electrode 140 may have a three-layer structure of ITO/Ag/ITO.

In an embodiment, a pixel defining layer 105 may be located on the first organic insulating layer 104 and may be disposed to cover the edges of the pixel electrode 140. For example, the pixel defining layer 105 may cover the edges of the pixel electrode 140. The pixel defining layer 105 may have an opening corresponding to the pixel PX, where the opening may be formed to expose at least the central portion of the pixel electrode 140. The pixel defining layer 105 may include organic materials such as polyimide or HMDSO. Also, a spacer 80 may be disposed on the pixel defining layer 105.

In an embodiment, the spacer 80 is shown to be located on the peripheral area PA, but the spacer 80 may also be located on the display area DA. The spacer 80 may prevent damage to the organic light-emitting diode due to the sagging of the mask in the manufacturing process using a mask. The spacer 80 may include organic insulating material and may be formed as a single layer or multiple layers.

In an embodiment, an intermediate layer 150 and an opposite electrode 160 may be located on the opening of the pixel defining layer 105. The intermediate layer 150 may include low molecular or high molecular materials, and in the case of including low molecular materials, the intermediate layer 150 may include a Hole Injection Layer, a Hole Transport Layer, an Emission Layer, an Electron Transport Layer, and/or an Electron Injection Layer. If the intermediate layer 150 includes high molecular materials, the intermediate layer 150 typically may have a structure including the Hole Transport Layer and the Emission Layer.

In an embodiment, the opposite electrode 160 may include a transparent conductive layer including a transparent conductive oxide such as ITO, In₂O₃ or IZO. In an embodiment, the pixel electrode 140 is used as an anode, and the opposite electrode 160 is used as a cathode. In another embodiment, the polarity of the electrodes may be applied in reverse.

The structure of the intermediate layer 160 is not limited to the above description and may have various structures. For example, in an embodiment, at least one of the layers constituting the intermediate layer 150 may be formed integrally with the opposite electrode 160. In another embodiment, the intermediate layer 150 may include a layer patterned to correspond to each of the plurality of pixel electrodes 140.

In an embodiment, the opposite electrode 160 may be disposed on the upper portion of the display area DA and may be disposed on the entire front of the display area DA. For example, the opposite electrode 160 may be integrally formed to cover a plurality of pixels. The opposite electrode 160 may be electrically contacted with a common power supply line (not shown) disposed in the peripheral area PA. In an embodiment, the opposite electrode 160 may extend to the barrier wall 200. The thin film encapsulation layer TFE may cover the entire display area DA, extend towards the peripheral area PA, and be disposed to cover at least the portion of the peripheral area PA.

In an embodiment, the thin film encapsulation layer TFE may extend to the outside of the common power supply line (not shown), where the thin film encapsulation layer TFE may include a first inorganic encapsulation layer 310, a second inorganic encapsulation layer 330, and an organic encapsulation layer 320 interposed between the first inorganic encapsulation layer 310 and the second inorganic encapsulation layer 330. The first inorganic encapsulation layer 310 and the second inorganic encapsulation layer 330 may include one or more inorganic materials such as aluminum oxide, titanium oxide, tantalum oxide, hafnium oxide, zinc oxide, silicon oxide, silicon nitride, silicon oxynitride.

In an embodiment, the first inorganic encapsulation layer 310 and the second inorganic encapsulation layer 330 may be a single layer or multiple layers including the aforementioned materials. The first inorganic encapsulation layer 310 and the second inorganic encapsulation layer 330 may include the same material or different materials. The thickness of the first inorganic encapsulation layer 310 and the second inorganic encapsulation layer 330 may be different. The thickness of the first inorganic encapsulation layer 310 may be greater than the thickness of the second inorganic encapsulation layer 330. Or, the thickness of the second inorganic encapsulation layer 330 may be greater than the thickness of the first inorganic encapsulation layer 310, or the thickness of the first inorganic encapsulation layer 310 and the second inorganic encapsulation layer 330 may be the same.

In an embodiment, the organic encapsulation layer 320 may include materials of the monomer series or polymer series. Polymer series materials may include acrylic resin, epoxy resin, polyimide and polyethylene. In an embodiment, the organic encapsulation layer 320 may include acrylate.

In an embodiment, a barrier wall 200 may be located on the peripheral area PA of the substrate 100. In an embodiment, the barrier wall 200 may include a three-layer structure including a portion 230 of the first organic insulating layer 104, a portion 220 of the pixel defining layer 105, and a portion 210 of the spacer 80, but the barrier wall 200 is not necessarily limited to the three-layer structure. For example, in another embodiment, the barrier wall 200 may have a two-layer structure including two layers among the portion 230 of the first organic insulating layer 104, the portion 220 of the pixel defining layer 105, and the portion 210 of the spacer 80.

In an embodiment, the barrier wall 200 may be disposed to surround the display area DA and may prevent the organic encapsulation layer 320 of the thin film encapsulation layer TFE from overflowing to the outside of the substrate 100. Therefore, the organic encapsulation layer 320 may contact the inner side of the barrier wall 200 facing the display area DA. When the phrase “the organic encapsulation layer 320 contacts the inner side of the barrier wall 200” is used, the phrase may be understood to mean that the first inorganic encapsulation layer 310 is located between the organic encapsulation layer 320 and the barrier wall 200, and the organic encapsulation layer 320 contacts the first inorganic encapsulation layer 310.

In an embodiment, the first inorganic encapsulation layer 310 and the second inorganic encapsulation layer 330 may be disposed on the barrier wall 200 and may extend towards the edge of the substrate 100. In an embodiment, multiple barrier walls 200 may be included in the display apparatus.

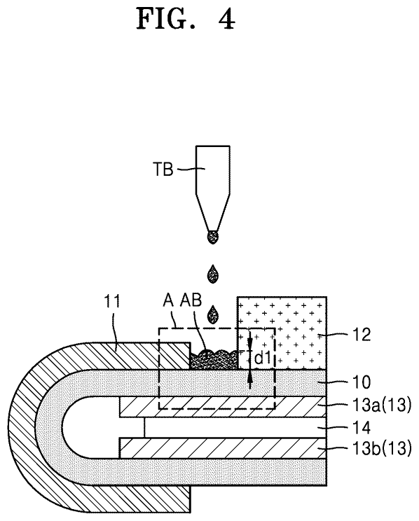

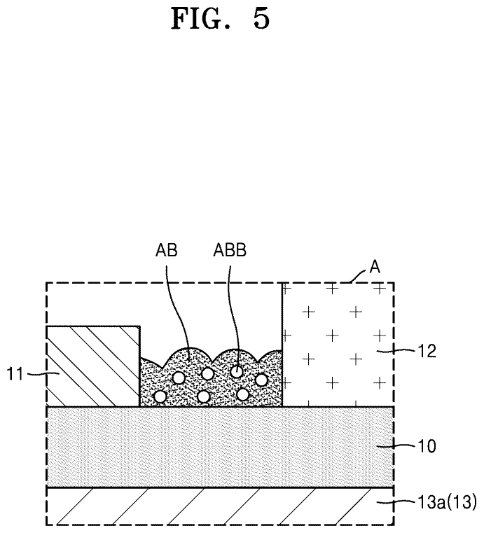

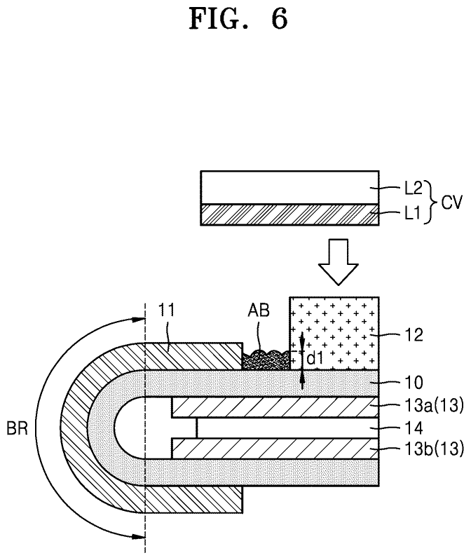

FIG. 4 is a cross-sectional view illustrating a portion of the display apparatus of FIG. 1 in a bent state, according to an embodiment, FIG. 5 is a cross-sectional view illustrating the A region of FIG. 4, according to an embodiment, and FIGS. 6 to 8 are cross-sectional views illustrating a portion of the display apparatus of FIG. 1 in a bent state, according to an embodiment.

For reference, FIGS. 4, 6 to 8 are drawings sequentially showing the display apparatus, according to a method of manufacturing the display apparatus using a laser process.

In an embodiment and as shown in FIG. 4, the display apparatus may further include the display panel 10, an upper protective layer 12, a bending protective layer 11, and a light-absorbing layer AB.

In an embodiment, the display panel 10 may be divided into the display area DA where an image is displayed and the peripheral area PA surrounding the display area DA. As mentioned above, the peripheral area PA may include the bending area BR which can be bent around the bending axis.

In an embodiment, the upper protective layer 12 may be disposed on the display panel 10. The upper protective layer 12 may be attached to the top surface of the display panel 10. The upper protective layer 12 may be disposed on the display panel 10 in the display area DA.

In an embodiment, the upper protective layer 12 may be disposed between the cover layer CV to be described below (see FIG. 6) and the display panel 10. The upper protective layer 12 may attach the cover layer CV to the display panel 10. For example, the upper protective layer 12 may be formed through a process of dispensing a UV-curable resin by an ink-jet printing method and curing the UV-curable resin with ultraviolet light.

In an embodiment, the bending protective layer 11 may cover the bending area BR of the display panel 10 and may be disposed on the display panel 10 in the bending area BR.

In an embodiment, the bending protective layer 11 may overlap with at least a portion of the main area AE1 of the display panel 10. In a plan view, the bending protective layer 11 may overlap with the bending area BR, a portion of the main area AE1, and at least a portion of the sub-area AE2. The bending protective layer 11 may completely cover the bending area BR.

In an embodiment, the bending protective layer 11 may be spaced apart from the upper protective layer 12. In a plan view, the bending protective layer 11 may not overlap with the upper protective layer 12.

In an embodiment, when the bending protective layer 11 is bent along an imaginary axis of the bending area BR, the bending protective layer 11 may be bent together with the display panel to protect the bending area BR of the display panel from external impacts. The bending protective layer 11 may protect the fan-out wiring FB disposed along the bending area BR from external impacts and the like.

In an embodiment, the bending protective layer 11 may include polymer resins such as polyethylene terephthalate PET or polyimide PI. The bending protective layer 11 may have a planar shape larger than a planar shape of the bending area BA. When viewed in a plan view, the bending area BA may be disposed inside the bending protective layer BPL.

In an embodiment, the light-absorbing layer AB may be a component for absorbing laser beams or UV wavelength light used in the laser process. The light-absorbing layer AB may be a component for preventing damage from the laser process.

For example, in an embodiment, the UV wavelength may be about 100 nanometers or more and about 400 nanometers or less.

For example, in an embodiment, the UV wavelength absorption rate of the light-absorbing layer AB may be about 90% or more. If the UV wavelength absorption rate is less than about 90%, the fan-out wiring FB and other components below the light-absorbing layer AB may be damaged by the laser beam. For example, the UV wavelength transmittance of the light-absorbing layer AB may be less than about 10%.

For example, in an embodiment, the recovery rate of the light-absorbing layer AB may be about 90% or more, and the elongation rate may be about 10% or more. If the recovery rate of the light-absorbing layer AB is less than about 90% and the elongation rate is less than about 10%, cracks may occur in the light-absorbing layer AB in the bent state.

For example, in an embodiment, the adhesion of the light-absorbing layer AB may be about 300 gf/inch or more. If the adhesion of the light-absorbing layer AB is less than about 300 gf/inch, the light-absorbing layer AB may detach from the display panel 10 in the bent state.

In an embodiment, the light-absorbing layer AB may be disposed on the display panel 10 to be located between the bending area BR and the display area DA. The light-absorbing layer AB may be disposed on the display panel 10 between the upper protective layer 12 and the bending protective layer 11.

In an embodiment, the light-absorbing layer AB may overlap with one edge of the cover layer CV in a plan view. For example, one edge of the cover layer CV formed by cutting through the laser process may overlap with the light-absorbing layer AB in a plan view. One edge may be formed by laser cutting. The UV wavelength transmittance of the light-absorbing layer AB is preferably less than about 10%.

For example, in an embodiment, a portion of the upper surface of the display panel may be exposed between the upper protective layer 12 and the bending protective layer 11. The light-absorbing layer AB may cover the exposed upper surface of the display panel facing upward.

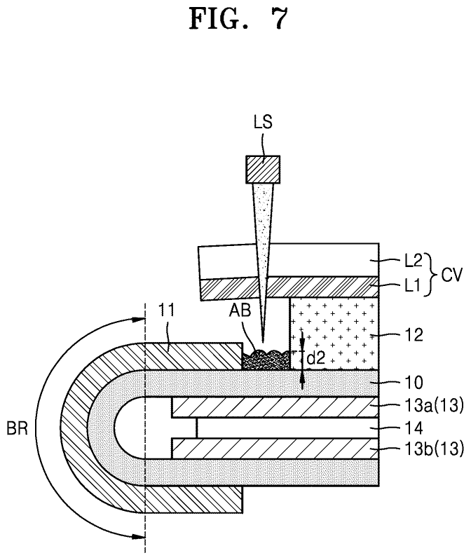

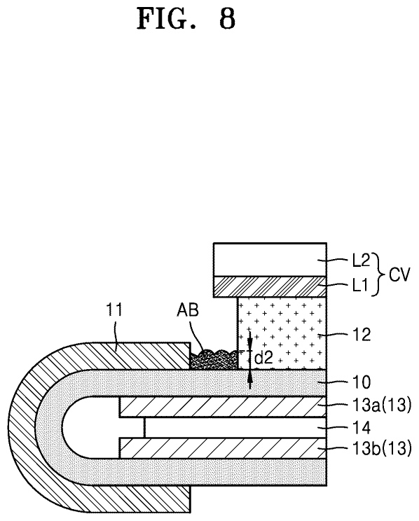

In an embodiment, the average thickness d1 of the light-absorbing layer AB may decrease due to the laser process. For example, the average thickness d1 of the light-absorbing layer AB before using the laser process may be larger than the average thickness d2 of the light-absorbing layer AB after using the laser process (see FIGS. 7 and 8 for reference).

For example, in an embodiment, the average thickness d1 of the light-absorbing layer AB may be about 30 micrometers or more and about 100 micrometers or less. If the average thickness d1 of the light-absorbing layer AB is less than about 30 micrometers, achieving the UV wavelength absorption rate of about 90% or more may be difficult, and if the average thickness d1 of the light-absorbing layer AB is greater than about 100 micrometers, the light-absorbing layer AB may interfere with the cover layer CV when attaching the cover layer CV as the thickness of the light-absorbing layer AB is similar to the height of the bending protective layer 11 or the upper protective layer 12. The preferred average thickness d1 of the light-absorbing layer AB may be about 50 micrometers.

In an embodiment, the resin dispensing device TB may drop the resin containing a plurality of light-absorbing agents ABB between the upper protective layer 12 and the bending protective layer 11 to form the light-absorbing layer AB. The light-absorbing layer AB may be formed when the resin discharged (or dropped) from the resin dispensing device TB is cured. Methods such as thermal curing or photo-curing may be used for curing.

In an embodiment, the adhesive layer 13 may include a first adhesive layer 13a and a second adhesive layer 13b. The first adhesive layer 13a may be adhered to the bottom surface of the display panel 10. The first adhesive layer 13a may be disposed between the display panel 10 and the lower layer 14, and may adhere the display panel 10 to the upper surface of the lower layer 14. The first adhesive layer 13a may include at least one of OCA (optical clear adhesive), PSA (pressure sensitive adhesive), thermoactivated adhesive, general adhesive, or double-sided tape.

In an embodiment, the lower layer 14 may have a single layer structure or a multilayer structure. For example, the lower layer 14 may include a polymer member and/or a metal sheet layer.

In an embodiment, the polymer member not shown may have a dark color applied for example, black to help display the background when the display is turned off. As an example, the polymer member not shown may act as a cushion to absorb external impacts and prevent damage to the display apparatus.

In an embodiment, the metal sheet layer not shown may help reinforce the rigidity of the display apparatus, shield surrounding noise, and disperse heat emitted from surrounding heat-emitting components. As an example, the metal sheet layer not shown may include at least one of SUS steel use stainless for example, STS stainless steel, Cu, Al, or CLAD for example, a laminated member with SUS and Al alternately disposed. Also, the metal sheet layer not shown may include other alloy materials.

In an embodiment, the second adhesive layer 13b may be adhered to the bottom surface of the display panel 10. The second adhesive layer 13b may be disposed between the display panel 10 and the lower layer 14, and may adhere the bottom surface of the display panel 10 to the upper surface of the lower layer 14. The second adhesive layer 13b may include at least one of OCA optical clear adhesive, PSA pressure sensitive adhesive, thermoactivated adhesive, general adhesive, or double-sided tape.

From the perspective of the manufacturing method of the display apparatus, the display apparatus of FIG. 4 can be described according to an embodiment as follows.

In an embodiment and as shown in FIG. 4, the method of manufacturing the display apparatus may include disposing an upper protective layer 12 on the display area DA of the display panel 10, disposing the bending protective layer 11 on the bending area BR of the display panel 10, and forming the light-absorbing layer AB including the plurality of light-absorbing agents ABB between the upper protective layer 12 and the bending protective layer 11 in a plan view.

In an embodiment, the step of forming the light-absorbing layer AB may be a step of applying the resin to protect the upper surface of the display panel 10 exposed upward between the upper protective layer 12 and the bending protective layer 11.

In an embodiment and as shown in FIG. 5, the light-absorbing layer AB may include the plurality of light-absorbing agents ABB. For example, the light-absorbing layer AB may be a resin layer including the plurality of light-absorbing agents ABB.

In an embodiment, each of the plurality of light-absorbing agents ABB may be a carbon black particle having a diameter of about 150 nanometers or less. In addition, each of the plurality of light-absorbing agents ABB may include a material which can absorb light in the UV wavelength band. For example, each of the plurality of light-absorbing agents ABB may include at least one of carbon black, graphite, chromium-based materials, dyes, metal reflective films, and light-absorbing films.

In an embodiment and as shown in FIG. 6, the display apparatus may further include the cover layer CV disposed on the upper protective layer 12. For example, the cover layer CV may be attached to the top surface of the upper protective layer 12. The cover layer CV may be disposed on the upper protective layer 12 and may overlap with the display area DA in a plan view. At least some of the edges of the cover layer CV may overlap with the peripheral area PA in a plan view.

In an embodiment, the cover layer CV may include a first layer L1 disposed on the upper protective layer 12, and a second layer L2 disposed on the first layer L1 and including a resin.

In an embodiment, the first layer L1 may be, for example, a Polyethylene Terephthalate layer (PET). The first layer L1 may have high light transmittance and may protect the display panel 10 from external impacts. The first layer L1 may be disposed between the upper protective layer 12 and the second layer L2.

In an embodiment, the second layer L2 may be disposed on the first layer L1 and may be a resin layer including a resin. The second layer L2 may have high light transmittance unlike the aforementioned light-absorbing layer AB and may have characteristics which are easily cut by the laser used in the laser process.

In an embodiment, the cover layer CV in FIG. 6 may be the cover layer CV before being cut by the laser process. Therefore, in a plan view, the cover layer CV may overlap with the light-absorbing layer AB. In a plan view, the cover layer CV may overlap with a portion of the bending protective layer 11. In a plan view, the cover layer CV may overlap with the bending area BR and simultaneously overlap with a portion of the bending protective layer 11. In a plan view, one edge of the cover layer CV may overlap with the portion of the bending protective layer 11, and may be located more outward for example, based on the center of the display panel 10 than the bending protective layer 11 in a plan view.

For example, in an embodiment, among the edges of the cover layer CV, the edge closest to the bending area BR may overlap with the light-absorbing layer AB in a plan view. For example, the thickness d1 of the light-absorbing layer AB may be less than the thickness of the bending protective layer 11, where the thickness of the bending protective layer 11 may be less than the thickness of the upper protective layer 12.

From the perspective of the manufacturing method of the display apparatus, the display apparatus of FIG. 6 can be described as follows.

In an embodiment and as shown in FIG. 6, the method of manufacturing the display apparatus may further include a step of disposing the cover layer CV on the upper protective layer 12.

In an embodiment, the step of disposing the cover layer CV on the upper protective layer 12 may include preparing the cover layer CV having a larger area than the upper surface area of the upper protective layer 12, and placing or attaching the cover layer CV on the upper surface of the upper protective layer 12.

In an embodiment and as shown in FIG. 7, the cover layer CV may be cut through the laser process, where the laser process may be suitable for cutting the first layer L1, which is a PET layer, and the second layer L2, which includes the resin.

In an embodiment, a laser gun LS emitting a laser beam may be disposed separated in a direction that is perpendicular to the light-absorbing layer AB, or may irradiate the laser beam towards the light-absorbing layer AB from above the light-absorbing layer AB. Specifically, the laser gun LS may irradiate the laser beam on the cover layer CV. The laser beam may pass through the cover layer CV and reach the light-absorbing layer AB. As a result, other components disposed below the light-absorbing layer AB for example, fan-out wiring FB, etc. may be prevented from being damaged by the laser beam due to the light-absorbing layer AB.

In an embodiment, the cross-section of the cover layer CV and the light-absorbing layer AB may be simultaneously disposed in the path of the laser beam. One edge of the cover layer CV and the light-absorbing layer AB may be simultaneously disposed in the path of the laser beam.

From the perspective of the manufacturing method of the display apparatus, the display apparatus of FIG. 7 can be described as follows.

In an embodiment and as shown in FIG. 7, the method of manufacturing the display apparatus may further include a step of cutting the cover layer CV using the laser process.

In an embodiment, the step of cutting the cover layer CV may be performed through a laser process which irradiates the laser beam at a certain position. The edge area of the cover layer CV extending towards the bending area BR may be cut and removed by the laser beam. In this process, the light-absorbing layer AB is a component for protecting the components disposed under the cover layer CV from the laser beam. After the edge area is removed, one edge of the cover layer CV formed by the laser process may overlap with the light-absorbing agent ABB in a plan view.

In an embodiment, the average thickness of the light-absorbing layer AB may decrease due to the laser process. For example, the average thickness d1 of the light-absorbing layer AB before the cutting step see FIGS. 4 to 6 for reference may be larger than the average thickness d2 of the light-absorbing layer AB after the cutting step. For example, the average thickness d2 of the light-absorbing layer AB may be less than the thickness of the bending protective layer 11.

For example, in an embodiment, the average thickness d2 of the light-absorbing layer AB after the cutting step may be greater than about 10 micrometers. If the average thickness d2 of the light-absorbing layer AB after the cutting step is designed to be less than about 10 micrometers, there is a possibility that components disposed below the light-absorbing layer AB, such as fan-out wiring FB, may be damaged by the laser process.

In an embodiment and as shown in FIG. 8, the display apparatus after the cover layer CV has been cut by the laser process may include the light-absorbing layer AB with a reduced average thickness d2.

In an embodiment, the light-absorbing layer AB may be partially damaged by the laser process. As a result, the average thickness d2 of the light-absorbing layer AB may be less than the average thickness d1 before applying the laser process.

In an embodiment, the cross-section of the cover layer CV cut by the laser process may overlap with the light-absorbing layer AB in a plan view, and may not overlap with the bending protective layer 11. The cross-section of the cover layer CV cut by the laser process may not overlap with the upper protective layer 12 in a plan view.

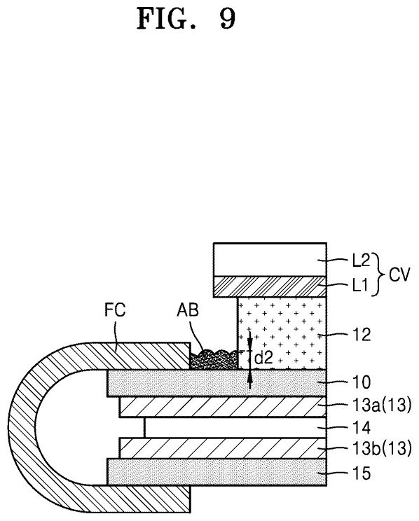

FIG. 9 is another example of a cross-sectional view illustrating a portion of a display apparatus, according to another embodiment. For reference, in the explanation of FIG. 9, content which is identical or overlapping with the above description may be omitted.

In an embodiment and as shown in FIG. 9, the display apparatus may include a flexible circuit board FC instead of the display panel 10 being bent. The flexible circuit FC may be electrically connected to one end of the display panel 10 and may be bent around a bending axis not shown.

In an embodiment, the flexible circuit board FC may be spaced apart from the upper protective layer 12, and the display panel 10 exposed upward between the flexible circuit board FC and the upper protective layer 12 may be covered by the light-absorbing layer AB.

In an embodiment, the manufacturing method of the display apparatus in FIG. 9 may also use the laser process. The cover layer CV may be cut by the laser process. The cross-section of the cover layer CV formed by the laser process may overlap with the light-absorbing layer AB in a plan view. The cross-section of the cover layer CV formed by the laser process may not overlap with the flexible circuit board FC in a plan view.

In an embodiment, the display panel 10 of the display apparatus in FIG. 9 may not include the bending area BR unlike the display panel 10 of the display apparatus in FIGS. 1 to 8. The lower layer 14 may be disposed below the display panel 10, and the first adhesive layer 13a may be disposed between the lower layer 14 and the display panel 10, and the first adhesive layer 13a may attach the bottom surface of the display panel 10 to the top surface of the lower layer 14.

In an embodiment, an additional lower layer 15 may be further disposed below the lower layer 14. The second adhesive layer 13b may be disposed between the lower layer 14 and the additional lower layer 15, and the second adhesive layer 13b may attach the bottom surface of the lower layer 14 to the top surface of the additional lower layer 15.

In an embodiment, the additional lower layer 15 may further include a separate polymer member not shown and/or a separate metal sheet layer not shown. The separate polymer member not shown may have the same characteristics as the polymer member not shown which may be included in the lower layer 14. The separate metal sheet layer not shown may have the same characteristics as the metal sheet layer not shown which may be included in the lower layer 14.

The manufacturing method of the display apparatus according to FIGS. 4 to 8 can be described as follows.

According to an embodiment, a method of manufacturing a display apparatus may include disposing an upper protective layer 12 on the display area DA of the display panel 10, disposing the bending protective layer 11 on the bending area BR of the display panel 10, forming the light-absorbing layer AB including the plurality of light-absorbing agents ABB between the upper protective layer 12 and the bending protective layer 11 in a plan view, forming the cover layer CV on the upper protective layer 12 and cutting the cover layer CV using the laser process, wherein the average thickness of the light-absorbing layer AB may decrease due to the laser process, and the average thickness of the light-absorbing layer AB before the cutting step may be larger than the average thickness of the light-absorbing layer AB after the cutting step. The average thickness of the light-absorbing layer AB may decrease due to the laser process, and the average thickness of the light-absorbing layer AB before the cutting step may be larger than the average thickness of the light-absorbing layer AB after the cutting step.

In an embodiment, the light-absorbing layer AB may be the resin layer including the plurality of light-absorbing agents ABB, and each of the plurality of light-absorbing agents ABB may be the carbon black particle having the diameter of about 150 nanometers or less.

In an embodiment, the UV wavelength transmittance of the light-absorbing layer AB including the plurality of light-absorbing agents ABB may be less than about 10%, and the thickness of the light-absorbing layer AB may be less than the thickness of the bending protective layer 11, and the thickness of the bending protective layer 11 may be less than the thickness of the upper protective layer 12.

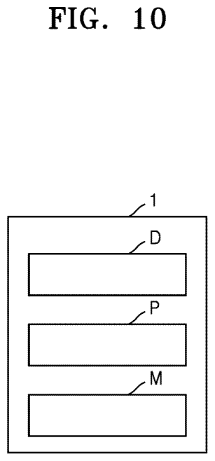

FIG. 10 is a conceptual diagram illustrating an electronic device including the display apparatus of FIG. 1, according to an embodiment. The display apparatus mentioned in FIG. 10 may be one of the examples of the display apparatus mentioned in FIGS. 1 to 9.

In an embodiment and as shown in FIG. 10, an electronic device 1 may include the aforementioned display apparatus D, a processor P, and a memory M.

In an embodiment, the electronic device 1 may include mobile phones, tablet PCs, laptops, wrist-worn smart watches or smart bands, etc. The electronic device 1 may be used as a broad term encompassing various products such as home appliances, computing devices, portable electronic devices, etc. which utilize the aforementioned display apparatus D.

In an embodiment, the electronic device 1 may include the memory M for storing instructions, the processor P for computing the instructions stored in the memory M to generate control commands, and the display apparatus D for displaying images based on the control commands generated by the processor P.

In an embodiment, the display apparatus D included in the electronic device 1 may be any one of the examples of the display apparatus described in FIGS. 1 to 9. For example, the display apparatus D included in the electronic device 1 may include the display panel 10 including the display area DA and the peripheral area PA including the bending area BR.

In an embodiment, the display apparatus D included in the electronic device 1 may further include an upper protective layer 12 disposed on the display panel 10, the cover layer CV disposed on the upper protective layer 12 and overlapping with the display area DA in a plan view, and a bending protective layer 11 disposed on the display panel 10 in the bending area BR.

In an embodiment, the display apparatus D included in the electronic device 1 may further include the light-absorbing layer AB disposed on the display panel 10 between the upper protective layer 12 and the bending protective layer 11, overlapping with one edge of the cover layer CV in a plan view, and including the plurality of light-absorbing agents ABB.

For example, in an embodiment, the light-absorbing layer AB may be the resin layer including the plurality of light-absorbing agents ABB, and the thickness of the light-absorbing layer AB may be less than the thickness of the bending protective layer 11, and the thickness of the bending protective layer 11 may be less than the thickness of the upper protective layer 12.

Other features of the display apparatus D may be the same as described in FIGS. 1 to 9, so the descriptions of the other features may be omitted.

As described above, according to an embodiment, the display apparatus, the method of manufacturing the same, and an electronic device which can minimize damage during the manufacturing process can be implemented.

As such, while the invention has been described with reference to exemplary embodiments shown in the drawings, the exemplary embodiments are only exemplary and those skilled in the art will understand which various modifications and equivalent other embodiments are possible.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display apparatus comprising:
a display panel divided into a display area where an image is displayed and a peripheral area surrounding the display area, wherein the peripheral area includes a bendable bending area;
an upper protective layer disposed on the display panel in the display area;
a cover layer disposed on the upper protective layer and overlapping with the display area in a plan view;
a bending protective layer disposed on the display panel in the bending area; and
a light-absorbing layer disposed on the display panel between the upper protective layer and the bending protective layer, wherein the light-absorbing layer overlaps with one edge of the cover layer in a plan view, and includes a plurality of light-absorbing agents.

2. The display apparatus of claim 1, wherein
the light-absorbing layer comprises a resin layer including the plurality of light-absorbing agents.

3. The display apparatus of claim 2, wherein
each of the plurality of light-absorbing agents comprises carbon black particles, wherein each of the carbon black particles have a diameter of about 150 nanometers or less.

4. The display apparatus of claim 1, wherein
among edges of the cover layer, an edge disposed closest to the bending area overlaps with the light-absorbing layer in a plan view.

5. The display apparatus of claim 1, wherein the cover layer comprises:
a first layer disposed on the upper protective layer; and
a second layer disposed on the first layer and including a resin.

6. The display apparatus of claim 1, wherein
the one edge is formed by laser cutting.

7. The display apparatus of claim 1, wherein
ultraviolet (UV) wavelength transmittance of the light-absorbing layer is less than about 10%.

8. The display apparatus of claim 1, wherein
a thickness of the light-absorbing layer is less than a thickness of the bending protective layer.

9. The display apparatus of claim 8, wherein
the thickness of the bending protective layer is less than a thickness of the upper protective layer.

10. A method of manufacturing a display apparatus including a display panel divided into a display area where an image is displayed and a peripheral area surrounding the display area, wherein the peripheral area includes a bendable bending area, the method comprising:
disposing an upper protective layer on the display area;
disposing a bending protective layer on the bending area;
forming a light-absorbing layer including a plurality of light-absorbing agents disposed between the upper protective layer and the bending protective layer in a plan view;
forming a cover layer on the upper protective layer; and
cutting the cover layer by using a laser process,
wherein an average thickness of the light-absorbing layer decreases due to the laser process.

11. The method of claim 10, wherein
the average thickness of the light-absorbing layer before the cutting is greater than the average thickness of the light-absorbing layer after the cutting.

12. The method of claim 10, wherein
one edge of the cover layer formed by the laser process overlaps with the light-absorbing agent in a plan view.

13. The method of claim 10, wherein
the light-absorbing layer comprises a resin layer including the plurality of light-absorbing agents.

14. The method of claim 13, wherein
each of the plurality of light-absorbing agents comprises carbon black particles, wherein each of the carbon black particles have a diameter of about 150 nanometers or less.

15. The method of claim 10, wherein
ultraviolet (UV) wavelength transmittance of the light-absorbing layer is less than about 10%.

16. The method of claim 10, wherein
a thickness of the light-absorbing layer is less than a thickness of the bending protective layer.

17. The method of claim 16, wherein
the thickness of the bending protective layer is less than a thickness of the upper protective layer.

18. An electronic device comprising:
a memory storing instructions;
a processor generating control commands by computing the instructions; and
a display apparatus displaying an image based on the control commands,
wherein the display apparatus comprises:
a display panel divided into a display area where an image is displayed and a peripheral area surrounding the display area, wherein the peripheral area includes a bendable bending area;
an upper protective layer disposed on the display panel;
a cover layer disposed on the upper protective layer and overlapping with the display area in a plan view;
a bending protective layer disposed on the display panel in the bending area; and
a light-absorbing layer disposed on the display panel between the upper protective layer and the bending protective layer, overlapping with one edge of the cover layer in a plan view, and including a plurality of light-absorbing agents.

19. The electronic device of claim 18, wherein
the light-absorbing layer comprises a resin layer including the plurality of light-absorbing agents.

20. The electronic device of claim 18, wherein
a thickness of the light-absorbing layer is less than a thickness of the bending protective layer, and the thickness of the bending protective layer is less than a thickness of the upper protective layer.
